(19) United States
(12) Patent Application Publication
(10) Pub. No.: US 2024/0385270 A1
(43) Pub. Date: Nov. 21, 2024

(54) SYSTEM AND METHOD FOR DENOISING IN MAGNETIC RESONANCE IMAGING USING A TRANSFORM DOMAIN LOCAL LOW RANK TECHNIQUE

(71) Applicant: Regents of the University of Minnesota, Minneapolis, MN (US)

(72) Inventors: Steen Moeller, Minneapolis, MN (US); Mehmet Akçakaya, Minneapolis, MN (US)

(21) Appl. No.: 18/669,423

(22) Filed: May 20, 2024

Related U.S. Application Data
(60) Provisional application No. 63/503,307, filed on May 19, 2023.

(51) Int. Cl. G01R 33/56; G01R 33/561; G01R 33/565; G06T 5/10; G06T 5/70

(52) U.S. Cl. CPC G01R 33/5608; G01R 33/5611; G01R 33/56545; G06T 5/10; G06T 5/70; G06T 2207/10088; G06T 2207/20056; G06T 2207/20081

(57) ABSTRACT

A system and method for denoising magnetic resonance images (MRI) in a transform domain are provided. In one aspect, the method incudes reconstructing a series of images of the target using the image data, transforming the series of images into a transform domain, and selecting patches in the image domain. The patches can be used to form matrices that can be decomposed to distinguish signal and noise components. Thresholding can be applied to remove the noise components in the transform domain. The denoised data can be inversely transformed back to the image domain to produce denoised images.

### RELATED APPLICATIONS

This application claims priority under 35 U.S.C. § 119 to U.S. Provisional Patent Application No. 63/503,307 filed on May 19, 2023, the entire contents of which is incorporated herein by reference.

### STATEMENT OF FEDERALLY SPONSORED RESEARCH

This invention was made with government support under EB025144 and EB027061 awarded by the National Institutes of Health. The government has certain rights in the invention.

### BACKGROUND

Magnetic resonance imaging methods continue to develop as researchers and clinicians push towards higher spatial resolution and faster scan times. However, signal to noise ratio (SNR) is generally directly proportional to the voxel size and the square root of the acquisition time. Thus, increasing the spatial resolution and accelerating the imaging come at the cost of SNR. Moreover, some imaging techniques that provide specialized contrasts, such as diffusion weighted imaging, are inherently SNR-starved. To combat low SNR, several post-processing techniques have been developed to reduce noise, including low-rank techniques that extract image features and suppress image noise. Low-rank techniques are either applied globally to the whole image series or in a local manner to image patches. The latter technique, referred to as locally low-rank (LLR) regularization, has been widely used for magnetic resonance (MR) image series.

LLR techniques typically rely on either a larger number (tens) of images in the series or identification of many regions across images with similar features for noise suppression. The similarity over tens of time-points is used to separate signal from noise. Current LLR techniques for post reconstruction improvements utilize an approach where a local patch of size N×N or N×N×N voxels is extracted from each M time-points. Noise components are suppressed by hard or soft thresholding of the singular values based on the singular value decomposition (SVD) of the N²×M or N³×M Casorati matrix. One particular LLR technique is referred to as noise reduction with distribution corrected (NORDIC) principal component analysis (PCA) denoising. In NORDIC, the threshold is chosen based on a non-asymptotic random matrix characterization of the thermal noise.

While conventional LLR methods can successfully reduce noise without deteriorating resolution, they often require an imaging series with a large number of volumes (e.g., >40). Thus, these techniques may either necessitate long scan times or may be limitedly applicable to types of imaging that inherently require a large number of volumes, such as functional MRI (fMRI), arterial spin labeling (ASL), diffusion, etc. Thus, new systems and methods are needed that expand the use of post-processing techniques to smaller data sets.

### SUMMARY OF THE DISCLOSURE

The present disclosure provides a method for reconstructing denoised magnetic resonance images. The method includes accessing k-space data with a computer system and reconstructing a series of images from the k-space data using the computer system. Transform domain data are generated by using the computer system to apply a linear transform to the series of images to transform the series of images into a transform domain. Denoised data are generated by applying a denoising algorithm in the transform domain data using the computer system, and a denoised image is generated by transforming the denoised data to an image domain using the computer system to apply an inverse of the linear transform to the denoised data.

It is another aspect of the present disclosure to provide a method for denoising magnetic resonance images, which includes accessing a series of images with a computer system. A linear transform is applied to the images using the computer system to generate transform domain data. Denoised data are generated by applying a singular value thresholding using a locally low-rank (LLR) model to the transform domain data using the computer system, and denoised images are generated from the denoised data by using the computer system to transform the denoised data into image space.

It is yet another aspect of the present disclosure to provide a method for denoising magnetic resonance images, which includes accessing k-space data with a computer system. The method further includes using the computer system to generate denoised data by applying a singular value thresholding using an LLR model to the k-space data. The method further includes generating a denoised image by transforming the denoised data to an image domain using the computer system to apply a linear transform to the denoised data.

The foregoing and other aspects and advantages of the present disclosure will appear from the following description. In the description, reference is made to the accompanying drawings that form a part hereof, and in which there is shown by way of illustration preferred embodiments. These embodiments do not necessarily represent the full scope of the invention, however, and reference is therefore made to the claims and herein for interpreting the scope of the invention.

### BRIEF DESCRIPTION OF THE DRAWINGS

FIG. 1A is a flowchart setting forth the steps of an example method for generating denoised magnetic resonance images using a denoising algorithm in a transform domain.

FIG. 1B is a flowchart setting forth the steps of another example method for generating denoised magnetic resonance images using a denoising algorithm in a transform domain.

FIG. 2 is a flowchart setting forth the steps of an example method for a denoising algorithm that may be applied in the transform domain in accordance with some embodiments of the systems and methods described in the present disclosure.

FIG. 3 is a block diagram of an example system for generating denoised magnetic resonance images according to some embodiments described in the present disclosure.

FIG. 4 is a block diagram of example components that can implement the system of FIG. 3.

FIG. 5 is a block diagram of an example MRI system that can implement the methods described in the present disclosure.

FIG. 6 outlines a flow diagram of an example implementation of the denoising methods described herein.

FIG. 7 shows example experimental results comparing LLR-based denoising applied in the image domain and k-space domain.

FIG. 8 shows example experimental results comparing denoising methods applied with varying linear transforms.

### DETAILED DESCRIPTION

Signal to noise ratio (SNR) in magnetic resonance imaging (MRI) is proportional to the voxel size and the square root of the acquisition time. Thus, with technological advances that strive towards improved spatial resolutions and faster imaging, many scans end up in a depleted SNR regime. The need for higher resolutions and faster imaging is even more pronounced in applications where multiple MR images are acquired across time or different contrasts, including functional MRI (fMRI), MR relaxometry, diffusion MRI (dMRI), arterial spin labeling (ASL), dynamic contrast-enhanced MRI, and so forth.

To improve SNR, numerous techniques have been proposed for denoising of MR image series, including those based on low-rank approaches, block matching self-similarity, and nonlocal means. Low-rank techniques are either applied globally to the whole image series or in a local manner to image patches. The latter technique, referred to as locally low-rank (LLR) regularization, has been widely used for MR image series such as dMRI, fMRI, and ASL, while also being used for cardiac imaging, multiparametric mapping, and relaxometry. Block matching self-similarity, and nonlocal means have been applied for corresponding applications, and despite the stronger suppression of noise, they are less widely adopted due to challenges for quantitative modelling related to accuracy of voxelwise signal changes.

More recently, a line of work that utilizes ideas from random matrix theory (RMT) has established parameter-free denoising for removing signals that cannot be distinguished from independent and identically distributed (i.i.d.) Gaussian noise for LLR regularization. Current LLR techniques for post-reconstruction improvements utilize an approach where a local patch of size N×N or N×N×N voxels is extracted from each of M time-points. Noise components are suppressed by hard or soft thresholding of the singular values based on the singular value decomposition (SVD) of the N²×M or N³×M Casorati matrix. In one particular LLR technique, referred to as noise reduction with distribution corrected (NORDIC) principal component analysis (PCA) denoising, the threshold is chosen based on a non-asymptotic random matrix characterization of the thermal noise. Note that for these LLR denoising techniques, the goodness of such representations depends on the rank of the underlying matrix, where lower rank enhances the likelihood of retaining all relevant image components after thresholding.

The present disclosure presents a transform-domain approach for LLR denoising of MR image series that aims to represent the underlying signal with high fidelity using a lower rank approximation. While a unitary transformation of the images in an MRI series would not affect the global rank, this is not the case for LLR processing. When the images are spatially transformed using a unitary transformation, then the underlying Casorati matrices of the transform domain image series may be represented with lower ranks. Furthermore, unitary transformations ensure that the independent and identically distributed nature of additive Gaussian noise is preserved, thus allowing use of the random matrix theory framework for parameter-free thresholding. As one non-limiting example, the transform domain approach can be applied in the spatial Fourier transform domain of the image series. For example, the transform domain may be k-space. The lower rank nature of the signal representation in the transform domain is used to enable the denoising of MR image series with as few as 4 volumes, using either complex k-space data, complex image data, or magnitude data. Thresholding can be applied by experimentally determining a threshold parameter or using various random-matrix-theory-based approaches to automatically determine the singular value thresholding parameter.

Thus, described herein are systems and methods for generating magnetic resonance images in which noise is significantly reduced. In general, a noise reduction algorithm, such as a locally low rank (LLR) method, is applied in a transform domain. As one non-limiting example, the locally low rank method for noise reduction may include a noise reduction with distribution corrected (“NORDIC”) denoising technique.

In particular, a transform domain denoising approach is described that utilizes spatial-temporal properties of noise in a transform domain to improve imaging data, without a need for imposing assumptions on underlying image signals. Thus, the transform-domain-based denoising approach can produce higher image SNR without deteriorating resolution. This allows for improved imaging and more accurate quantitative analyses and parameters obtained therefrom. Applying the low rank denoising in the transform domain can improve SNR in cases where standard LLR methods are insufficient. Furthermore, the use of transform domain denoising can reduce the observable effects of denoising in the image domain as compared to standard approaches. In some non-limiting embodiments, the noise variance reduction approach can comprise a transform domain LLR denoising (T-LLR) or a transform domain noise reduction with distribution corrected (T-NORDIC) principal component analysis (PCA) denoising.

The described technique advantageously allows for noise suppression using fewer volumes (e.g., 4-12) by applying the LLR principles in a transform domain. By applying the denoising in the transform domain, the technique may reduce noise in cases in which typical LLR methods are insufficient. Further, the use of the transform domain may reduce the undesirable effects of denoising in the image domain, like blocking artifact or spatial blurring. Thus, the technique is widely applicable for many sequence types without the need for greatly increased scan times. Further, the technique can be applied to image data that has already been reconstructed for parallel imaging and coil combination or applied on the original data in a channel-independent way. Thus, the transform domain denoising methods may be flexibly applicable in conjunction with a wide variety of other reconstruction methods. Moreover, the reduced requirement for number of imaging volumes can allow for shorter scan times, facilitating integration with quantitative MRI protocols (e.g., quantitative mapping), especially those subject to low SNR.

Commonly used denoising techniques in MRI rely on linear processing, such as Gaussian or Hanning filters, which trade off noise reduction with a deteriorated point-spread-function, thereby affecting spatial resolution. An alternative strategy, based on compressed sensing (“CS”), uses non-linear processing, exploiting the underlying low-dimensional properties of the images (such as sparsity-based, data-driven or rank-based), to remove aliasing artifacts and reduce noise in the final reconstructed images. However, CS approaches require incoherent sampling of k-space, which can be achieved by random undersampling in Cartesian acquisitions or via non-Cartesian trajectories. This approach may not be advantageous in 2D single-shot EPI acquisitions, for instance, which are favored in functional MRI (“fMRI”) and diffusion-weighted (“dMRI”) methods. CS also relies on computationally expensive iterative processing, which alternately enforces data consistency with acquired k-space and regularization based on low-dimensionality. Furthermore, the choice of regularization parameters in CS-based approaches is often done empirically, making it difficult to streamline across different anatomies. In addition, the combination of simultaneous multi-slice (“SMS”) and multi-band (“MB”) imaging, which is commonly used in dMRI and fMRI, with CS has been shown to have some drawbacks relative to a combination of SMS/MB and parallel imaging (“PI”) in two-dimensional imaging.

By contrast, the LLR approach described in the present disclosure utilizes the advantages of non-linear processing. As an advantage, the disclosed techniques can be utilized with a wide range of acquisition strategies, including SMS/MB EPI acquisitions that are often used in fMRI and dMRI applications. Results from random matrix theory may be employed to derive pre-determined thresholding parameters, independent of the data acquisition. The thresholding can be performed before or after a parallel imaging reconstruction of the acquired image data to produce images with reduced noise.

In this manner, the systems and methods described in the present disclosure can provide improved performance of an MRI system by enabling data acquisition techniques for acquiring data that would otherwise result in noisy images or require the use of computationally intensive reconstruction techniques. The systems and methods described in the present disclosure can also improve the functioning of a computer system that is configured to reconstruct images from data acquired with an MRI system, or to process such images to reduce noise. For instance, the systems and methods described in the present disclosure can generate higher quality images with fewer computational resources than other methods, thereby improving the functioning of a computer system configured to generate such images.

In particular, the systems and methods described in the present disclosure utilize a locally low rank approach in a transform domain, whether applied before image reconstruction or in a post-processing step that is performed after image reconstruction. The use of LLR in linear transform domains, such as unitary transform domains like Fourier or wavelet domains or overcomplete transform domains, improves the underlying low rankness of the patches and preserves high-frequency content. In some examples, the noise can be considered homogeneous in the transform domain. Using a unitary transform may advantageously maintain the independently identically distributed (i.i.d.) nature of noise across coordinates in the transformed representation. Other transformations may alter the noise characteristics in a known way.

The disclosed T-NORDIC and T-LLR techniques can use overlapping blocks in the transform domain and a distance weighted approach for combining these blocks to achieve denoising. In some implementations, the overlapping blocks may be sparsely overlapping blocks. This approach reduces the computational complexity and allows for better noise removal. In some aspects, the transform domain denoising algorithm described in the present disclosure may utilize a multiscale approach by utilizing a weighted combination of patches having different dimensions and shapes to produce improved noise removal. This implementation takes advantage of additional redundancies in the input images to achieve improved local denoising. The present noise removal can be parameter free, and take into consideration image data noise level.

In some aspects, the systems and methods described in the present disclosure may process complex-valued signals that have been obtained in low SNR applications with an MRI system, such as susceptibility weighted imaging (“SWI”). The methods may be applied at various points in a variety of image reconstruction pipelines, making the method flexible and compatible with various types of reconstructions. To this end, the systems and methods described in the present disclosure may find a broad range of applications, including for reducing noise in images acquired with fMRI, diffusion, arterial spin labeling (“ASL”), relaxation mapping, Relaxation Along a Fictitious Field (RAFF), and other techniques, without needing to modify the underlying acquisition sequences.

It is recognized herein that low-dimensional information present in image data, acquired using common clinical pulse sequences (even those that yield aliasing artifacts that are coherent), can be leveraged to facilitate a CS-based reconstruction, particularly when performing a parallel imaging reconstruction. To this end, acquired fMRI or dMRI k-space data, for instance, may be reconstructed with standard parallel imaging methods, such as SENSE or GRAPPA. In some implementations, parallel imaging reconstruction can be performed in SNR units. This ensures that the underlying noise distribution corresponds to a standard normal distribution. Advantageously, the transform domain denoising approach described herein may be applied before or after standard parallel imaging reconstruction algorithms on individual channels or on channel-combined data. In some implementations, it may be advantageous to apply the denoising methods prior to parallel imaging reconstruction (e.g., SENSE, GRAPPA) as the i.i.d. nature of the noise is maintained.

Let m(r,τ)∈ [symbol] ^{I}^{₁}^{×I}^{₂}^{×I}^{₃}^{×T} be a complex-valued MR image series, where r denotes the location in 3D space, and τ∈{1, . . . , T} denotes a particular image in the series across different contrasts or time points. LLR approaches consider k₁×k₂×k₃ patches across the image in a sliding window manner. For a given point τ in the image series, this patch is vectorized to y_{τ}. These are then concatenated to generate a Casorati matrix Y=[y₁, . . . , y_{τ}, . . . , y_{N}]∈ [symbol] ^{M×T} with M=k₁k₂k₃. LLR denoising then aims to recover the corresponding underlying data matrix X, based on the additive noise model

$$Y = X + N ,$$

where N∈ [symbol] ^{M×T} is Gaussian noise.

LLR models assume that for a given patch across the volume, the data matrix X has a low-rank representation; that is, X can be well-represented, with a low Frobenius norm error, using the sum of a small number of rank-1 matrices.

Based on this assumption, LLR methods perform singular value thresholding using either hard or soft thresholding approaches. Singular values below threshold λ(j)<λₜₕᵣ are replaced by λ(j)=0. Those above the threshold either remain unchanged (in hard thresholding) or are reduced by λₜₕᵣ (in soft thresholding). For recent works that use random matrix theory (RMT) to characterize the singular value distribution of Y or N, the threshold λₜₕᵣ is chosen automatically in a parameterless manner based on different criteria, such as matching the tail of a Marchenko-Pastur distribution or ensuring i.i.d. Gaussian noise in N by pre-processing and then using the largest expected singular value of a finite Gaussian matrix (as in NORDIC).

While these recent RMT-based LLR denoising methods tackle a major issue in singular value thresholding by allowing parameter-free selection of the threshold without empirical trial-and-error, they still inherently assume that the signal components of the data matrix X only have corresponding singular values above the threshold λₜₕᵣ, and thus they are assumed to not be conflated with noise and are not removed during processing. This assumption largely relies on the quality of the low-rank representation.

The image series m(r,τ)∈ [symbol] ^{I}^{₁}^{×I}^{₂}^{×I}^{₃}^{×T} can be transformed to a transform domain and represented as \tilde{m}(r,τ)=Tₛm(r,τ), where Tₛ is a linear unitary transform, acting on r for each point in the image series. Again, Casorati matrix \tilde{Y}∈ [symbol] ^{M×T} can be formed as previously described, but now on \tilde{m}(r,τ). The denoising problem for this Casorati matrix is to recover the transform data matrix \tilde{X} from

$$\tilde{Y} = \tilde{X} + \tilde{N} ,$$

where Ñ∈ [symbol] ^{M×T} is Gaussian noise. Note that if the noise in m(r,τ) is i.i.d. Gaussian, so is the noise in \tilde{m}(r,τ), since the transform is unitary, allowing the use of RMT-based selection of the threshold parameter. After singular value thresholding on \tilde{Y}, the denoised image patches can be combined to generate an approximation, \tilde{z}(r,τ), to the spatially transformed MR image series \tilde{m}(r,τ). This can then be transformed back to image domain z(r,τ)=T_{S}⁻¹\tilde{z}(r,τ), as the final denoised estimate.

As one non-limiting example, Tₛ can be a spatial discrete Fourier transform (DFT). However, other transforms (e.g., discrete cosine transform, Walsh Hadamard, wavelet, and so forth) can also be used. Moreover, the transform can be applied along one or more dimensions in space (e.g., x, y, z), through time (e.g., along τ), or a combination thereof. The use of DFT as the unitary transform is natural in MRI applications, as data are acquired in the Fourier domain. Moreover, most vendor-supplied filters in MRI are convolutional in nature and thus implemented as pointwise multiplication in the Fourier domain. Advantageously, most features related to sampling (e.g., partial Fourier, elliptical, and non-uniform sub-Nyquist sampling) may all be naturally preserved when the DFT is used as a sparsifying transform.

In some implementations, the transform Tₛ can be a learned transform. As non-limiting examples, Tₛ can be learned using an auto-encoder network or other neural network that is trained on training data to learn a transform from one domain to another. For example, the learned transform can transform the data from an image domain to a transform domain, from a k-space domain to a transform domain, and the like. Such transform may be learned by training a machine learning algorithm on paired training data. The paired training data can include a set of data in the original domain (e.g., k-space or image space) each paired with corresponding data in a transform domain. Similarly, the inverse transform used to transform the data back to the original domain can also be a learned inverse transform.

The theoretical assumption for threshold selection in RMT-based LLR denoising is that the noise is i.i.d. Gaussian, which is consistent with thermal noise in the acquired data. Most MRI images are represented as DICOM images, in which case the noise is either Rician or non-central Chi\hat{ }2 and may also be spatially varying. The theoretical equations for the thermal noise of these in the transform domain is complicated, yet from the central limit theorem the transform of these distributions may be Gaussian. In such situations, the threshold selection applies and, by extension, the denoising in transform domains is more compatible with Gaussian based approaches than the image based equivalent.

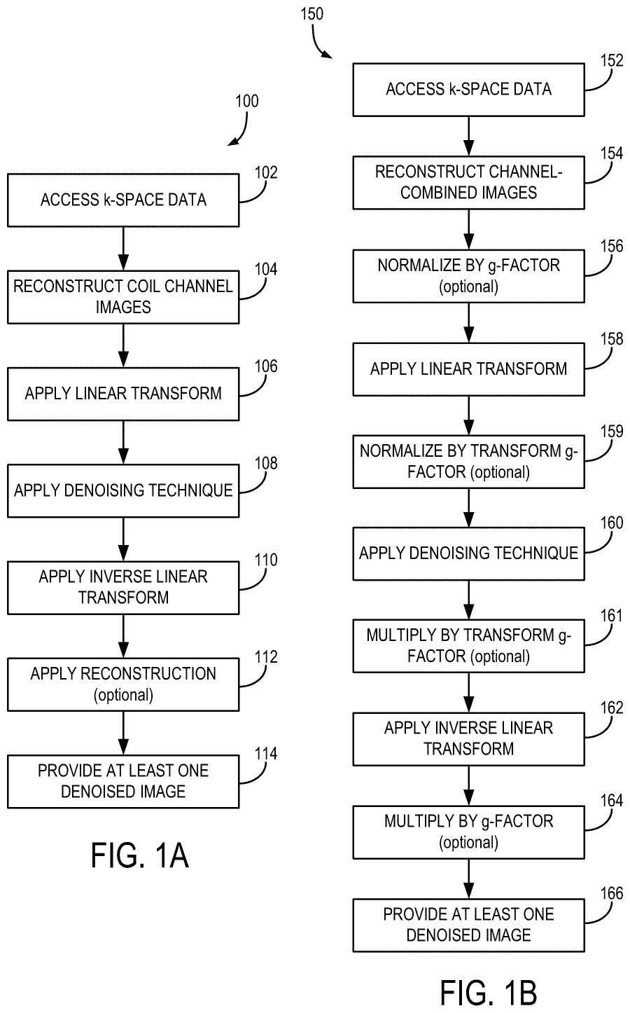

Referring now to FIGS. 1A and 1B, flowcharts setting forth steps of example processes 100 and 150 in accordance with aspects of some embodiments of the present disclosure are shown. The processes 100 and 150 may be carried out using any suitable system, computer, or device, including systems described in the present disclosure. In some implementations, the processes 100 and 150 may be embodied in a program, software, or instructions executable by a processor. The program, software, or instructions can be stored in a non-transitory computer readable medium, or other data storage location.

In general, processes 100 and 150 can be used to reconstruct denoised magnetic resonance images. The processes include accessing a series of k-space data and reconstructing an image series from the k-space data or accessing an image series. The image series data is transformed into a transform domain using a linear transform along at least one dimension (e.g., x, y, z, another spatial dimension, or time). The transform domain data is arranged into a matrix by selecting local patches in the transform domain data. A denoising algorithm can be applied to the matrix to enforce a low-rank representation of the matrix. The denoised data can be transformed back to the image domain by applying an inverse of the linear transform to provide denoised images.

In particular, the process 100 represents some embodiments of the present disclosure in which the transform domain denoising is performed prior to parallel imaging reconstruction or coil combination. The process 100 may begin at process block 102 with accessing k-space data acquired by an MRI system. The k-space data can include data that correspond to a series of images through time. Such series may include a dynamic series of images or a contrast-varying series of images. As an example, fMRI image data, diffusion image data, ASL image data, Relaxation Along a Fictitious Field (RAFF), and other image data may be acquired and accessed at process block 102. The k-space data may be fully sampled or undersampled and may be acquired with a single coil or multi-channel coil array. Image data may be acquired directly by an MRI system or acquired by accessing stored k-space data.

At process block 104, the k-space data can be reconstructed into a series of coil channel images. For example, the reconstruction of process block 104 may include a uniform fast Fourier transform, non-uniform Fourier transform, or other image reconstruction which maintains the complex signal. At this point, the channel data need not be combined and can be processed in a channel-independent way.

The images reconstructed in process block 104 may include magnitude images or complex images. In some implementations, process block 104 can include the removal of phase. As a non-limiting example, phase data can be calculated from the combination of channels (e.g., using a sensitivity-encoding (SENSE)-1 combination), and a median filter or other suitable filter can be applied to the phase data in order to smooth the phase data. The smoothed phase can be removed from the individual channels. In instances where the original k-space data are fully sampled, this removed phase can be ignored. When the original k-space data are undersampled, the removed phase may be advantageous for the subsequent image reconstruction. Therefore, in those instances the removed phase can be added back after the noise has been removed.

At process block 106, each coil channel image can be transformed into a transform domain by applying a linear transform. The transform can be applied along any combination of the spatial dimensions of each of the images. For example, the transform can be applied along just one spatial dimension (e.g., x, y, z, or oblique), along two or more spatial dimensions (e.g., any combination of two of x, y, z, and oblique, such as x and y), along all three spatial dimensions (e.g., along each of x, y, and z), etc. In some embodiments, the dimensions x, y, and z may correspond to the read-out, phase-encoded, and slice-encoded dimensions, respectively. In other embodiments, the dimensions x, y, and z may correspond to the read-out, a first phase-encoded, and a second phase-encoded dimensions, respectively. However, the transformation may be applied along oblique axes, as well. In some embodiments, a transform may also be applied along the temporal dimension (i.e., across the series of images), or along other domains (e.g., different contrast weightings). For example, a transform through time may be useful with fMRI, spectroscopy, etc. data to spectrally select which components to keep. Moreover, the type of linear transform applied can vary for each dimension, applying a different linear transform along different dimensions. For example, a DFT may be applied along x while a wavelet transform is applied along y, and so forth.

Process block 106 may include transforming the full series of images into a transform domain or may include transforming a subset of the images, which may include only a single image. For example, by applying the transform and subsequent denoising process to a subset of the series of images, the process 100 can achieve denoising of specific subsets of the available images. As a non-limiting example, this approach may provide shell-specific (i.e., same b-value but different q-vectors) denoising of diffusion MRI data. The process 100 can also be applied with a sliding window approach in which denoising is repeated for various combinations of images.

The transform in process block 106 may include any linear transforms. In some examples, the linear transform may be a unitary transform (i.e., a transform that preserves the inner product). For example, a unitary transform may be used, such as a fast Fourier transform, a Haar wavelet transform, or another unitary transform. The transform may also include an overcomplete transform. The denoising technique of process block 108 can be applied in the transform domain for each channel independently. As a nonlimiting example, process block 108 may comprise a NORDIC denoising algorithm, other LLR-based denoising algorithm based on random matrix theory, or another LLR-based denoising algorithm. The details of process block 108 will be described in further detail below.

After denoising, the denoised transform domain data for each channel can be transformed back to the image domain in process block 110. The transform of process block 110 can correspond to the inverse transform of that applied in process block 106. Process block 110 provides denoised coil channel images. The denoised channel images can be coil-combined or otherwise processed in optional process block 112. For example, parallel imaging reconstruction, such as SENSE, Generalized Autocalibrating Partially Parallel Acquisition (GRAPPA), etc., or simultaneous multislice (SMS) reconstruction, such as slice-GRAPPA, etc., may be applied. As another example, coil-combination may include SENSE 1 combination or root sum of squares combination. Other suitable image reconstruction techniques may be applied in process block 112 to provide denoised images in the desired format in process block 114. As yet another example, the reconstruction of process block 112 may include a non-linear and/or machine learning-based reconstruction. The images provided in process block 114 may be displayed, analyzed, or further processed to create quantitative maps, such as apparent diffusion coefficient maps from denoised dMRI data.

Referring now to FIG. 1B, process 150 illustrates some embodiments of the present disclosure in which the transform domain denoising is performed after parallel imaging reconstruction and coil combination. K-Space data can be accessed in process block 152, as similarly described in process block 102. In process block 152 the k-space data may be fully sampled or undersampled data acquired with a multi-channel coil array. The data can be reconstructed in process block 154 to produce unaliased, coil combined images. The images can be magnitude images, phase images, or complex images. For example, process block 154 may include parallel imaging or SMS reconstruction methods applied in the image or k-space domain. Process block 154 may also include a SENSE 1 or other coil combination that maintains the complex signal and Gaussian noise. Process block 154 can also include images that are coil-combined by root-sum-of-squares, which may have non-central chi-squared (χ²) noise.

If desired, in process block 154, a phase can be calculated from the combination of channels (e.g., using a SENSE 1 combination), and a median filter or other suitable filter can be applied to the phase data in order to smooth the phase data. The smoothed phase can be removed from the combination of channels. In instances where the original k-space data are fully sampled, this removed phase can be ignored. When the original k-space data are undersampled, the removed phase may be advantageous for the subsequent image reconstruction. Therefore, in those instances the removed phase can be added back after the noise has been removed.

In some implementations, the channel-combined images may be normalized by the g-factor in optional process block 156. The g-factor maps, for example, may be calculated based on the parallel imaging or SENSE 1 reconstruction applied in process block 154. In general, such g-factor maps depict a spatial distribution of the g-factor in the imaged volume. The images can be normalized by the g-factor maps in order to produce spatially uniform noise (e.g., Gaussian noise, or other spatially uniform noise), which may be advantageous for subsequent denoising (e.g., process block 160). However, the data may alternatively be normalized by the g-factor maps by applying the normalization in the transform domain, as will be described in further detail.

The channel-combined images can be transformed in process block 158 to a transform domain by applying a linear transform. As previously described, the transformation may be applied to the full image series or to a subset of images within the image series. The transforms can also be applied on one or more dimensions of the data, including spatial dimensions (such as x, y, z, etc.) or the temporal dimension (such as through the image series, b-value, contrast level, etc.), in various combinations.

The transform may be any linear transform. The linear transform can be a unitary transform, such as a fast Fourier transform, a Haar wavelet transform, or another unitary transform. The transform may also be an overcomplete transform. In some implementations, a the denoising algorithm can be applied directly to the k-space data. A unitary transform of process block 158 may maintain the Gaussian noise distribution in the transform domain to ensure the denoising technique can be applied in process block 160. Alternatively, the linear transformation may alter the noise in a known manner such that the noise distribution can be whitened accordingly. The noise may also be treated as locally Gaussian in the transform domain.

After applying a linear transform, g-factor normalization can be applied in the transform domain. In optional process block 159, the data can be normalized by the transform space g-factor, which represents the g-factor in the transform domain. Such normalization can maintain noise that is spatially uniform in the image domain, which may be advantageous for denoising applied in process block 160.

Denoising can be applied in process block 160. The details of a denoising technique that may be applied in process block 160 will be described in detail below. As a nonlimiting example, process block 160 may comprise a NORDIC denoising algorithm, other LLR-based denoising algorithm based on random matrix theory, or another LLR-based denoising algorithm.

If the data were normalized by the transform space g-factor maps in the transform domain in optional process block 159, the normalization can be reversed in optional process block 161. The data can be multiplied by the transform g-factor maps to re-normalize the data and obtain the original signal magnitude.

The denoised transform domain data can be transformed back into image space in process block 162 by applying the inverse transform of that applied in process block 158. Process block 162 provides a denoised channel-combined image.

If the noisy data was normalized by the g-factor maps in process block 156, the image signal produced by process block 162 will also be modulated by the g-factor maps. Thus, the denoised images can be re-normalized by multiplying the images by the g-factor maps to obtain the original signal magnitude.

Denoised channel-combined images are provided in process block 166. The images may be displayed, analyzed, or further processed to produce quantitative maps or other desired images.

In some implementations, processes 100 and 150 can be applied when access to the raw k-space data is not available. In this way, process blocks 102 and 104 and process blocks 152 and 154 may include accessing data that is already reconstructed as imaging data, rather than accessing k-space data and reconstructing images from such data. For example, images (e.g., DICOMs) may be accessed from an MRI system, hospital database, or other image database. In some implementations, such imaging data may be channel-combined or include coil-specific images. These images may include magnitude images, complex images, or phase images. This advantageously allows application of denoising methods when the raw (e.g., k-space) data is not available.

In some implementations, the transform domain may be the frequency or k-space domain. In this way, denoising can be applied directly to k-space data as mentioned above. In this case, process blocks 104 and 106 or 154, 156, 158, and 159 can be skipped, for example.

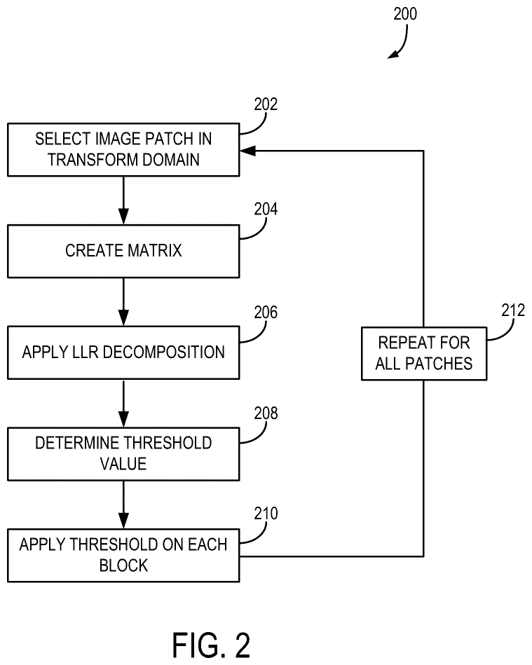

Referring now to FIG. 2, a flowchart setting forth the steps of process 200 in accordance with aspects of some embodiments of the present disclosure is shown. In particular, the process 200 provides steps for a denoising algorithm that may be applied in the transform domain. For example, the process 200 may be applied during processes 100 (e.g., at process block 108) and 150 (e.g., at process block 160) of FIGS. 1A and 1B, respectively.

At process block 202, patches in the transform domain of the series of images may be selected. For example, a k₁×k₂×k₃ image patch may be selected in the transform domain for each of the volumes t within the series, τ∈{1, . . . , T}. As a non-limiting example, the patch size may be selected as 4×4×4 pixels in the transform domain for T=4 volumes in the series.

For a given time point or volume, τ, each patch, which is positioned at the given pixel in the transform domain, is then vectorized to \tilde{y}_{τ} to be utilized to form a matrix. The vectors {\tilde{y}₁, . . . , \tilde{y}_{τ}, . . . , \tilde{y}_{T}} are grouped (e.g., concatenated) to form a matrix, as indicated by process block 204. As an example, a patch-based Casorati matrix, \tilde{Y}=[\tilde{y}₁, . . . , \tilde{y}_{τ}, . . . , \tilde{y}_{N}]∈ [symbol] ^{M×T}, where M=k₁k₂k₃, can be constructed, such that each column, \tilde{y}_{τ}, is composed of transform domain voxels in a fixed patch, k₁×k₂×k₃, from each volume τ∈{1, . . . , N}.

The denoising problem is then to recover the corresponding underlying data Casorati matrix, \tilde{X}, based on the model \tilde{Y}=\tilde{X}+Ñ, where Ñ∈ [symbol] ^{M×T} is noise, such as additive Gaussian noise. Due to redundancies in the image series that acquire the same anatomy over time or through contrast changes (e.g., across different contrast weightings), the Casorati matrix can be represented accurately by a low-rank matrix, which can be enforced via singular value thresholding (e.g., hard or soft thresholding) or other suitable techniques.

In process block 206, the Casorati matrix can be decomposed by singular value decomposition, SVD, as a non-limiting example. For example, the SVD of \tilde{Y} can be defined as U·S·V^{H}, where U and V are unitary matrices, and S is a diagonal matrix whose diagonals are the spectrum of ordered singular values, λ(j), j∈{1, . . . , N}.

The thresholding value, λₜₕᵣₑₛₕ, can be chosen in process block 208. For example, λₜₕᵣₑₛₕ may be chosen as in standard LLR techniques by heuristically defining λₜₕᵣₑₛₕ based on the data or based on the singular values λ(j). Such method may be referred to as T-LLR. As another example, λₜₕᵣₑₛₕ can be chosen based on a non-asymptotic random matrix characterization of the thermal noise, as is done in NORDIC methods, such as those described in co-pending U.S. Pat. No. 10,768,260, which is herein incorporated by reference in its entirety. In this case, a random Gaussian matrix can be formed. The Gaussian matrix can have a distribution that is similar to that of the noise in the data. The threshold can be determined based on the singular values of the random Gaussian matrix. Such method may be referred to as T-NORDIC.

In process block 210, the threshold (i.e., λₜₕᵣₑₛₕ) can be applied for each Casorati matrix. For example, hard thresholding can be applied where the singular values below the threshold λ(j)<λₜₕᵣₑₛₕ are replaced by λ(j)=0. Soft thresholding can also be applied where λ(j)<λₜₕᵣₑₛₕ are reduced to λ(j)=λₜₕᵣₑₛₕ. Thus, the low-rank estimate of \tilde{Y} becomes \tilde{Y}_{L}=U·S_{λ}_{ₜₕᵣₑₛₕ}·V^{H}, suppressing the noise and maintaining the signal components.

This process can be repeated, as in process block 212, for other patches to cover the whole transform domain. The patches can be non-overlapping to reduce computational times or overlapping to reduce blocking artifacts. The patches may be shifted by half a patch size in each direction, for instance. Patches of different scales, sizes and shapes may also be utilized, providing benefits to CS-based approaches and image denoising. The Casorati matrix may then be formed in process block 204 using a distance weighted approach combining the sparsely overlapping blocks.

If the image data is not channel combined, the process can additionally be applied to each coil channel image and repeated for each channel. The locally low-rank estimates can be combined to generate denoised image series.

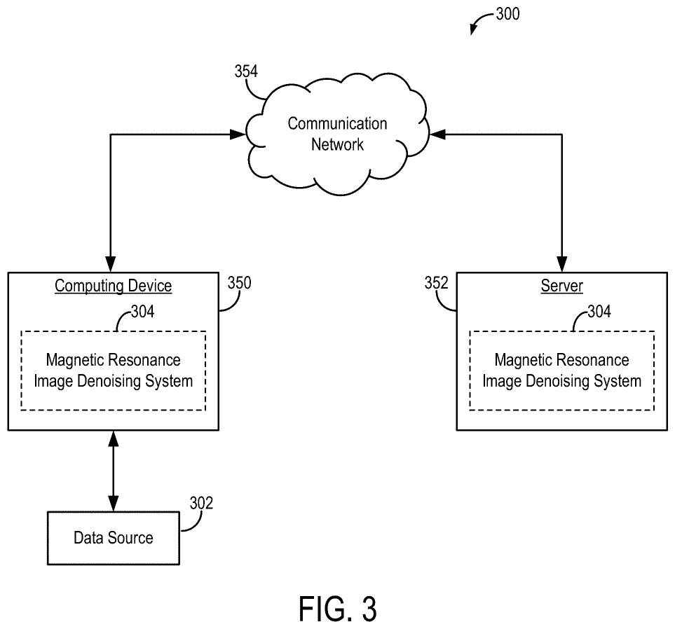

Referring now to FIG. 3, an example of a system 300 for generating denoised images in accordance with some embodiments of the systems and methods described in the present disclosure is shown. As shown in FIG. 3, a computing device 350 can receive one or more types of data (e.g., k-space data, training data) from data source 302, which may be a k-space data source. In some embodiments, computing device 350 can execute at least a portion of a magnetic resonance image denoising system 304 to reconstruct denoised magnetic resonance images from k-space data received from the data source 302.

Additionally or alternatively, in some embodiments, the computing device 350 can communicate information about data received from the image source 302 to a server 352 over a communication network 354, which can execute at least a portion of the magnetic resonance image denoising system 304. In such embodiments, the server 352 can return information to the computing device 350 (and/or any other suitable computing device) indicative of an output of the magnetic resonance image denoising and reconstruction.

In some embodiments, computing device 350 and/or server 352 can be any suitable computing device or combination of devices, such as a desktop computer, a laptop computer, a smartphone, a tablet computer, a wearable computer, a server computer, a virtual machine being executed by a physical computing device, and so on. The computing device 350 and/or server 352 can also reconstruct images from the data.

In some embodiments, data source 302 can be any suitable source of data (e.g., measurement data, images reconstructed from measurement data), such as an MRI system, another computing device (e.g., a server storing k-space data), and so on. In some embodiments, data source 302 can be local to computing device 350. For example, data source 302 can be incorporated with computing device 350 (e.g., computing device 350 can be configured as part of a device for measuring, recording, estimating, acquiring, or otherwise collecting or storing data). As another example, data source 302 can be connected to computing device 350 by a cable, a direct wireless link, and so on. Additionally or alternatively, in some embodiments, data source 302 can be located locally and/or remotely from computing device 350, and can communicate data to computing device 350 (and/or server 352) via a communication network (e.g., communication network 354).

In some embodiments, communication network 354 can be any suitable communication network or combination of communication networks. For example, communication network 354 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some embodiments, communication network 354 can be a local area network, a wide area network, a public network (e.g., the Internet), a private or semi-private network (e.g., a corporate or university intranet), any other suitable type of network, or any suitable combination of networks. Communications links shown in FIG. 3 can each be any suitable communications link or combination of communications links, such as wired links, fiber optic links, Wi-Fi links, Bluetooth links, cellular links, and so on.

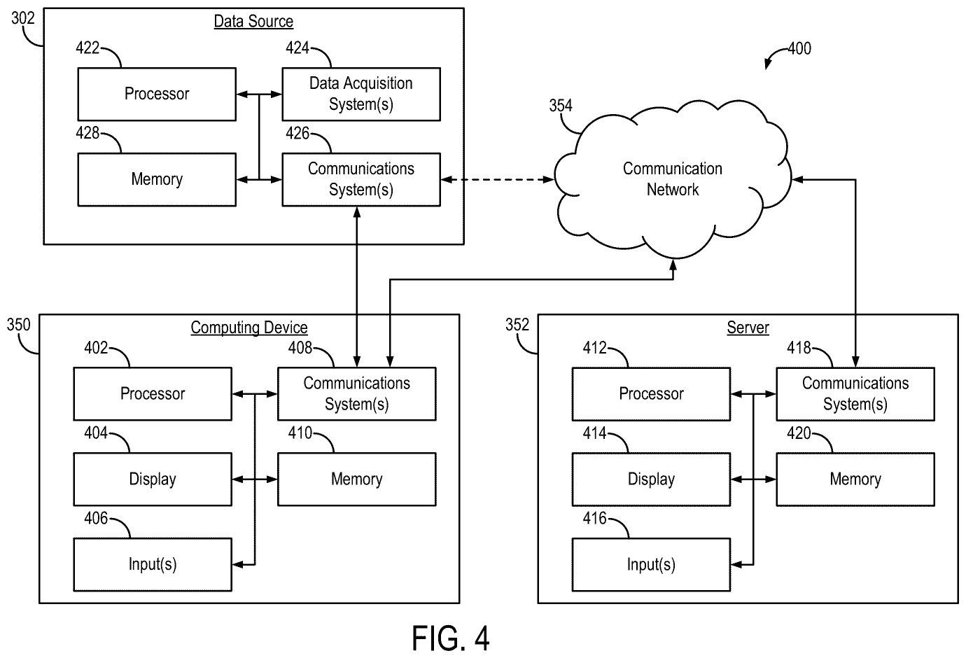

Referring now to FIG. 4, an example of hardware 400 that can be used to implement data source 302, computing device 350, and server 352 in accordance with some embodiments of the systems and methods described in the present disclosure is shown.

As shown in FIG. 4, in some embodiments, computing device 350 can include a processor 402, a display 404, one or more inputs 406, one or more communication systems 408, and/or memory 410. In some embodiments, processor 402 can be any suitable hardware processor or combination of processors, such as a central processing unit (“CPU”), a graphics processing unit (“GPU”), and so on. In some embodiments, display 404 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some embodiments, inputs 406 can include any suitable input devices and/or sensors that can be used to receive user input, such as a keyboard, a mouse, a touchscreen, a microphone, and so on.

In some embodiments, communications systems 408 can include any suitable hardware, firmware, and/or software for communicating information over communication network 354 and/or any other suitable communication networks. For example, communications systems 408 can include one or more transceivers, one or more communication chips and/or chip sets, and so on. In a more particular example, communications systems 408 can include hardware, firmware, and/or software that can be used to establish a Wi-Fi connection, a Bluetooth connection, a cellular connection, an Ethernet connection, and so on.

In some embodiments, memory 410 can include any suitable storage device or devices that can be used to store instructions, values, data, or the like, that can be used, for example, by processor 402 to present content using display 404, to communicate with server 352 via communications system(s) 408, and so on. Memory 410 can include any suitable volatile memory, non-volatile memory, storage, or any suitable combination thereof. For example, memory 410 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some embodiments, memory 410 can have encoded thereon, or otherwise stored therein, a computer program for controlling operation of computing device 350. In such embodiments, processor 402 can execute at least a portion of the computer program to present content (e.g., images, user interfaces, graphics, tables), receive content from server 352, transmit information to server 352, and so on. For example, the processor 402 and the memory 410 can be configured to perform the methods described herein (e.g., the method 100 of FIG. 1A; the method 150 of FIG. 1B; the method 200 of FIG. 2).

In some embodiments, server 352 can include a processor 412, a display 414, one or more inputs 416, one or more communications systems 418, and/or memory 420. In some embodiments, processor 412 can be any suitable hardware processor or combination of processors, such as a CPU, a GPU, and so on. In some embodiments, display 414 can include any suitable display devices, such as an LCD screen, LED display, OLED display, electrophoretic display, a computer monitor, a touchscreen, a television, and so on. In some embodiments, inputs 416 can include any suitable input devices and/or sensors that can be used to receive user input, such as a keyboard, a mouse, a touchscreen, a microphone, and so on.

In some embodiments, communications systems 418 can include any suitable hardware, firmware, and/or software for communicating information over communication network 354 and/or any other suitable communication networks. For example, communications systems 418 can include one or more transceivers, one or more communication chips and/or chip sets, and so on. In a more particular example, communications systems 418 can include hardware, firmware, and/or software that can be used to establish a Wi-Fi connection, a Bluetooth connection, a cellular connection, an Ethernet connection, and so on.

In some embodiments, memory 420 can include any suitable storage device or devices that can be used to store instructions, values, data, or the like, that can be used, for example, by processor 412 to present content using display 414, to communicate with one or more computing devices 350, and so on. Memory 420 can include any suitable volatile memory, non-volatile memory, storage, or any suitable combination thereof. For example, memory 420 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 420 can have encoded thereon a server program for controlling operation of server 352. In such embodiments, processor 412 can execute at least a portion of the server program to transmit information and/or content (e.g., data, images, a user interface) to one or more computing devices 350, receive information and/or content from one or more computing devices 350, receive instructions from one or more devices (e.g., a personal computer, a laptop computer, a tablet computer, a smartphone), and so on.

In some embodiments, the server 352 is configured to perform the methods described in the present disclosure. For example, the processor 412 and memory 420 can be configured to perform the methods described herein (e.g., the method 100 of FIG. 1A; the method 150 of FIG. 1B; the method 200 of FIG. 2).

In some embodiments, data source 302 can include a processor 422, one or more data acquisition systems 424, one or more communications systems 426, and/or memory 428. In some embodiments, processor 422 can be any suitable hardware processor or combination of processors, such as a CPU, a GPU, and so on. In some embodiments, the one or more data acquisition systems 424 are generally configured to acquire data, images, or both, and can include an MRI system. Additionally or alternatively, in some embodiments, the one or more data acquisition systems 424 can include any suitable hardware, firmware, and/or software for coupling to and/or controlling operations of an MRI system. In some embodiments, one or more portions of the data acquisition system(s) 424 can be removable and/or replaceable.

Note that, although not shown, data source 302 can include any suitable inputs and/or outputs. For example, data source 302 can include input devices and/or sensors that can be used to receive user input, such as a keyboard, a mouse, a touchscreen, a microphone, a trackpad, a trackball, and so on. As another example, data source 302 can include any suitable display devices, such as an LCD screen, an LED display, an OLED display, an electrophoretic display, a computer monitor, a touchscreen, a television, etc., one or more speakers, and so on.

In some embodiments, communications systems 426 can include any suitable hardware, firmware, and/or software for communicating information to computing device 350 (and, in some embodiments, over communication network 354 and/or any other suitable communication networks). For example, communications systems 426 can include one or more transceivers, one or more communication chips and/or chip sets, and so on. In a more particular example, communications systems 426 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some embodiments, memory 428 can include any suitable storage device or devices that can be used to store instructions, values, data, or the like, that can be used, for example, by processor 422 to control the one or more data acquisition systems 424, and/or receive data from the one or more data acquisition systems 424; to generate images from data; present content (e.g., images, a user interface) using a display; communicate with one or more computing devices 350; and so on. Memory 428 can include any suitable volatile memory, non-volatile memory, storage, or any suitable combination thereof. For example, memory 428 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some embodiments, memory 428 can have encoded thereon, or otherwise stored therein, a program for controlling operation of data source 302. In such embodiments, processor 422 can execute at least a portion of the program to generate images, transmit information and/or content (e.g., data, images) to one or more computing devices 350, receive information and/or content from one or more computing devices 350, receive instructions from one or more devices (e.g., a personal computer, a laptop computer, a tablet computer, a smartphone, etc.), and so on.

In some embodiments, any suitable computer-readable media can be used for storing instructions for performing the functions and/or processes described herein. For example, in some embodiments, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

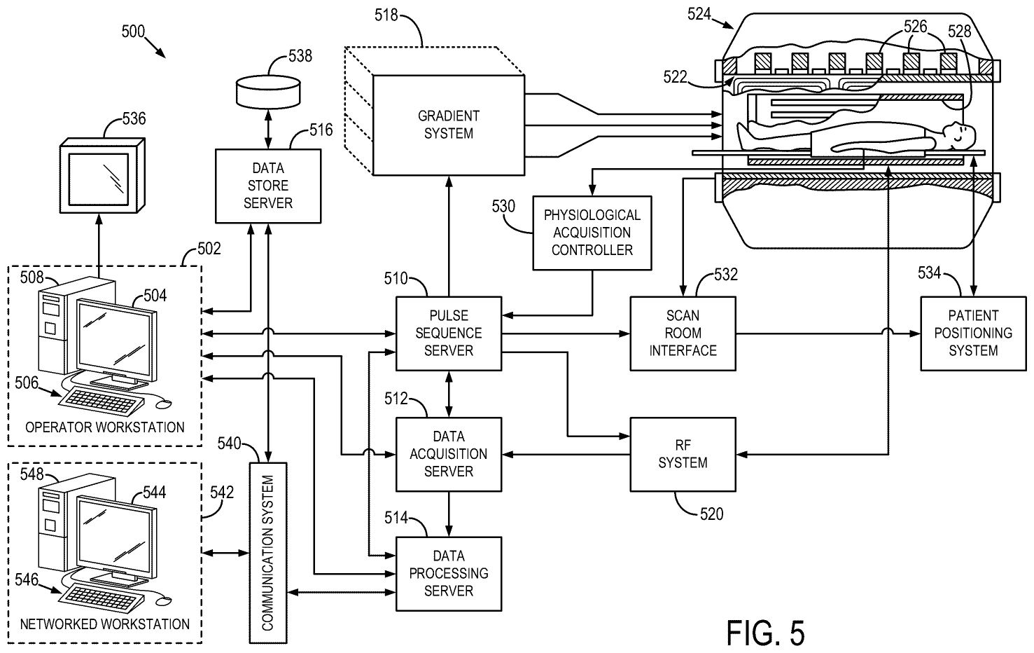

Referring particularly now to FIG. 5, an example of an MRI system 500 that can implement the methods described here is illustrated. The MRI system 500 includes an operator workstation 502 that may include a display 504, one or more input devices 506 (e.g., a keyboard, a mouse), and a processor 508. The processor 508 may include a commercially available programmable machine running a commercially available operating system. The operator workstation 502 provides an operator interface that facilitates entering scan parameters into the MRI system 500. The operator workstation 502 may be coupled to different servers, including, for example, a pulse sequence server 510, a data acquisition server 512, a data processing server 514, and a data store server 516. The operator workstation 502 and the servers 510, 512, 514, and 516 may be connected via a communication system 540, which may include wired or wireless network connections.

The pulse sequence server 510 functions in response to instructions provided by the operator workstation 502 to operate a gradient system 518 and a radiofrequency (“RF”) system 520. Gradient waveforms for performing a prescribed scan are produced and applied to the gradient system 518, which then excites gradient coils in an assembly 522 to produce the magnetic field gradients Gₓ, G_{y}, and G_{z} that are used for spatially encoding magnetic resonance signals. The gradient coil assembly 522 forms part of a magnet assembly 524 that includes a polarizing magnet 526 and a whole-body RF coil 528.

RF waveforms are applied by the RF system 520 to the RF coil 528, or a separate local coil to perform the prescribed magnetic resonance pulse sequence. Responsive magnetic resonance signals detected by the RF coil 528, or a separate local coil, are received by the RF system 520. The responsive magnetic resonance signals may be amplified, demodulated, filtered, and digitized under direction of commands produced by the pulse sequence server 510. The RF system 520 includes an RF transmitter for producing a wide variety of RF pulses used in MRI pulse sequences. The RF transmitter is responsive to the prescribed scan and direction from the pulse sequence server 510 to produce RF pulses of the desired frequency, phase, and pulse amplitude waveform. The generated RF pulses may be applied to the whole-body RF coil 528 or to one or more local coils or coil arrays.

The RF system 520 also includes one or more RF receiver channels. An RF receiver channel includes an RF preamplifier that amplifies the magnetic resonance signal received by the coil 528 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ;$$

and the phase of the received magnetic resonance signal may also be determined according to the following relationship:

$$φ = {tan}^{- 1} ( \frac{Q}{I} ) .$$

The pulse sequence server 510 may receive patient data from a physiological acquisition controller 530. By way of example, the physiological acquisition controller 530 may receive signals from a number of different sensors connected to the patient, including electrocardiogramaignals from electrodes, or respiratory signals from a respiratory bellows or other respiratory monitoring devices. These signals may be used by the pulse sequence server 510 to synchronize, or “gate,” the performance of the scan with the subject's heart beat or respiration.

The pulse sequence server 510 may also connect to a scan room interface circuit 532 that receives signals from various sensors associated with the condition of the patient and the magnet system. Through the scan room interface circuit 532, a patient positioning system 534 can receive commands to move the patient to desired positions during the scan.

The digitized magnetic resonance signal samples produced by the RF system 520 are received by the data acquisition server 512. The data acquisition server 512 operates in response to instructions downloaded from the operator workstation 502 to receive the real-time magnetic resonance data and provide buffer storage, so that data is not lost by data overrun. In some scans, the data acquisition server 512 passes the acquired magnetic resonance data to the data processor server 514. In scans that require information derived from acquired magnetic resonance data to control the further performance of the scan, the data acquisition server 512 may be programmed to produce such information and convey it to the pulse sequence server 510. For example, during pre-scans, magnetic resonance data may be acquired and used to calibrate the pulse sequence performed by the pulse sequence server 510. As another example, navigator signals may be acquired and used to adjust the operating parameters of the RF system 520 or the gradient system 518, or to control the view order in which k-space is sampled. In still another example, the data acquisition server 512 may also process magnetic resonance signals used to detect the arrival of a contrast agent in a magnetic resonance angiography (“MRA”) scan. For example, the data acquisition server 512 may acquire magnetic resonance data and processes it in real-time to produce information that is used to control the scan.

The data processing server 514 receives magnetic resonance data from the data acquisition server 512 and processes the magnetic resonance data in accordance with instructions provided by the operator workstation 502. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 514 are conveyed back to the operator workstation 502 for storage. Real-time images may be stored in a data base memory cache, from which they may be output to operator display 502 or a display 536. Batch mode images or selected real time images may be stored in a host database on disc storage 538. When such images have been reconstructed and transferred to storage, the data processing server 514 may notify the data store server 516 on the operator workstation 502. The operator workstation 502 may be used by an operator to archive the images, produce films, or send the images via a network to other facilities.

The MRI system 500 may also include one or more networked workstations 542. For example, a networked workstation 542 may include a display 544, one or more input devices 546 (e.g., a keyboard, a mouse), and a processor 548. The networked workstation 542 may be located within the same facility as the operator workstation 502, or in a different facility, such as a different healthcare institution or clinic.

The networked workstation 542 may gain remote access to the data processing server 514 or data store server 516 via the communication system 540. Accordingly, multiple networked workstations 542 may have access to the data processing server 514 and the data store server 516. In this manner, magnetic resonance data, reconstructed images, or other data may be exchanged between the data processing server 514 or the data store server 516 and the networked workstations 542, such that the data or images may be remotely processed by a networked workstation 542.

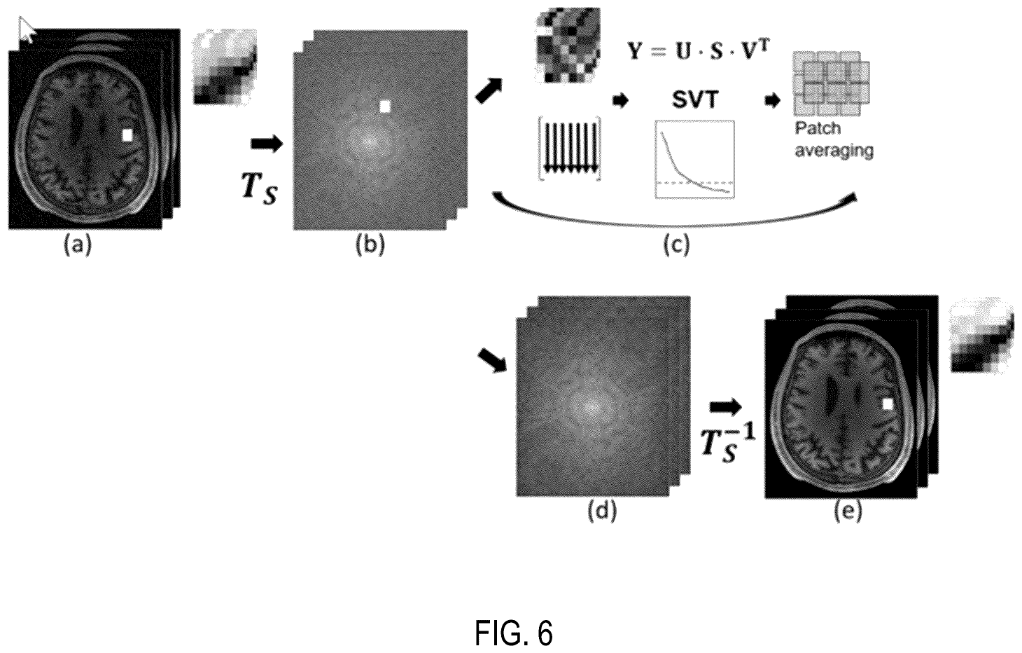

FIG. 6 outlines a flow diagram of an example implementation of T-LLR or T-NORDIC, as described in the present disclosure. The series of images (a) is processed with a unitary transform Tₛ. From the transform processed series (b), the same types of transform coefficients are used from each volume (c). For each patch, a Casorati matrix is constructed, SVD is applied, and a hard singular value threshold adapted. Each patch is then averaged together to form a denoised transform domain series (d), and the denoised imaging series is obtained with the inverse unitary transform (e). The zoomed sections in (a) and (e) represent the patches that can be used for image-based LLR denoising techniques. The zoomed section in (b) shows example patches that may be used for transform-domain approaches, as described herein.

In non-limiting examples provided, the disclosed transform-domain LLR denoising approach leads to high-quality denoising in MR relaxometry applications with as few as 4 to 12 contrast volumes, improving upon existing image domain based LLR methods that typically require a higher number of volumes in the image series.

In one example, a fully sampled multi-slice multi-echo (MSME) spin echo T₂ relaxation time mapping acquisition was chosen to demonstrate T-NORDIC under Gaussian i.i.d. thermal noise. A knee joint (i.e., stifle) of a piglet was imaged ex vivo using 3 T MRI with a 15 channel coil. Sequence parameters were: FOV=140×140 mm²; sampling matrix=512×512; in-plane resolution=0.27×0.27 mm²; slices=15; slice thickness/gap=2.0/0 mm; TR=2010 ms; TE=14, 28, 42, 56, 70, 84, 98, and 112 ms; partial Fourier=5/8; BW=250 Hz/px; fat saturation; scan time=11 min per repetition; and 20 repetitions. Denoising was applied to a single channel of the 15 channels and multi-channel data where the coils were combined using SENSE-1 processing.

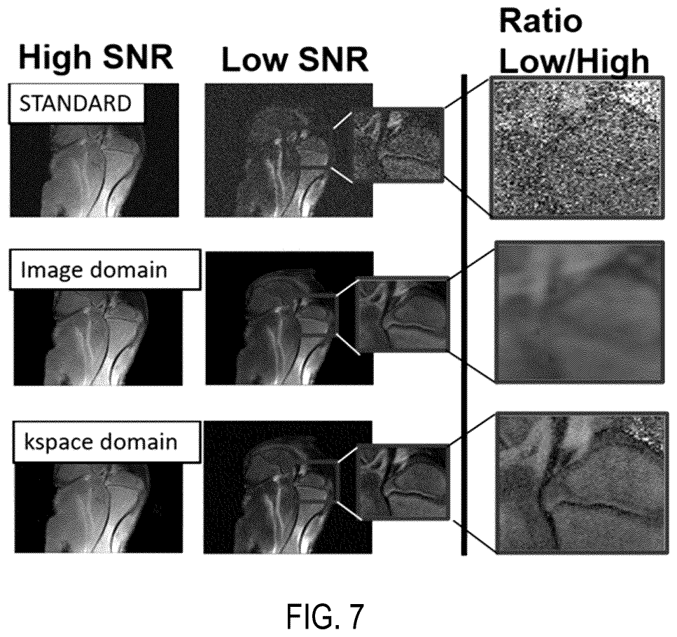

LLR was applied in the image domain and k-space as an example for how the LLR benefits from processing in a transform domain. For the described MSME spin-echo acquisition, the impact of the proposed transform domain denoising is shown in FIG. 7, where the first echo (high SNR) and the last echo (low SNR) are displayed. In this case, the SNR is reduced on average 90% between the first and the last echo images. The impact on the multi-contrast signal for a single channel, fully-sampled k-space is shown in image-space. Additionally, the ratio of the low and high SNR images is shown, highlighting the preservation of contrast in T-NORDIC. The ratio of the low SNR to the high SNR image also highlights the challenge of sharing image content between images using a low-rank constraint. The T-NORDIC k-space for the low SNR image illustrates how denoising in the transform domain preserves the magnitude of high spatial resolution features, whereas these are more suppressed with the image space based denoising.

While local patches in the original x-y-t domain exploit similarities across image series (e.g., based on an exponential decay for quantitative MRI), the local patches in the kₓ-k_{y}-t domain behave differently. A small patch in the center of this domain (assuming DFT) captures most of the energy and the underlying contrast information in the image series, which effectively acts like a global singular value decomposition on a very low-resolution image. In contrast, a small patch in outer parts of the kₓ-k_{y} domain through t captures high-frequency or edge information. For most applications (e.g., fMRI or quantitative MRI), the edge information remains consistent across the image series, thus this representation is able to model the underlying signal with very few components, improving the underlying rank.

In another example, T-NORDIC was applied to anatomical high resolution brain imaging data. This dataset comprised a 6-echo 3D GRE axial image slab (104 slices) with 0.35 mm isotropic resolution (TR=35 ms, TE=3.83, 8.2, 12.57, 16.94, 21.31, and 25.68 ms, flip angle=12°, no partial Fourier, 576×576 matrix). 4 runs of data (˜1 hour) were combined to support a high-resolution high-SNR T₂* map, which was then used to generate simulated real-valued T₂* weighted data with real-valued Gaussian noise.

T-NORDIC was implemented using a patch size of 5×5×5. This choice was made based on an 11:1 ratio as a good balance between denoising and accurate signal representation. Patch averaging was used with a stride of 2, to ensure at least 8 averages for each denoised value. The threshold selection was implemented as the highest singular value from a Casorati matrix with i.i.d. entries with a variance estimated from the data.

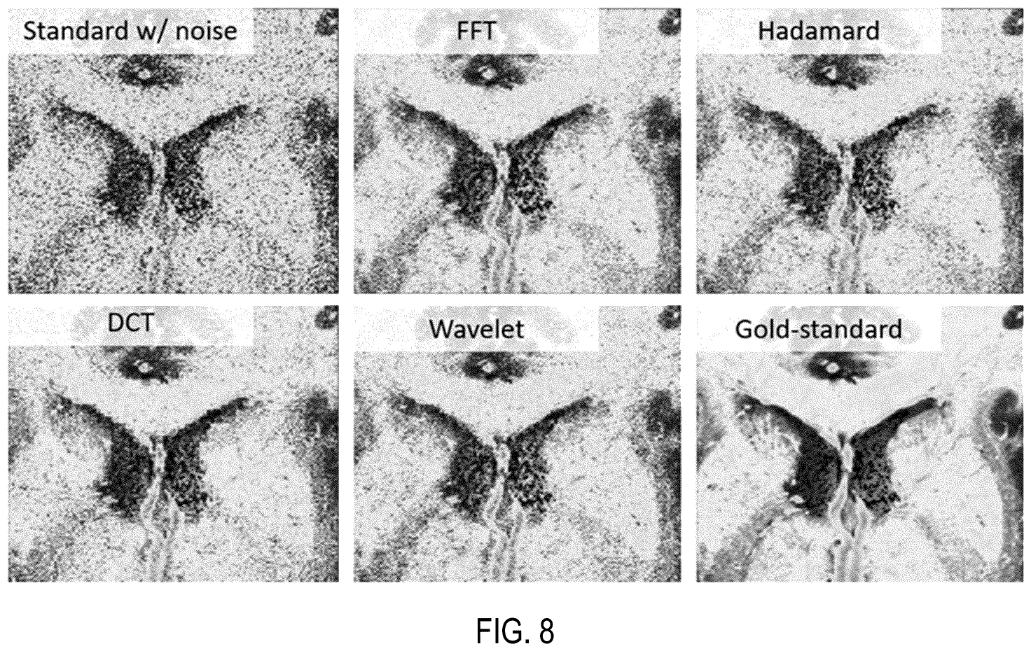

The T-NORDIC implementation of transform domain LLR denoising was tested for the effect of different unitary transforms, including DFT, DCT, Walsh-Hadamard and wavelet transform. The results, which are presented in FIG. 8, demonstrate a negligible difference between the transforms for a real valued signal with real valued gaussian noise.

The present disclosure has described one or more preferred embodiments, and it should be appreciated that many equivalents, alternatives, variations, and modifications, aside from those expressly stated, are possible and within the scope of the invention.

1. A method for reconstructing denoised magnetic resonance images, the method comprising:
(a) accessing k-space data with a computer system;
(b) reconstructing a series of images from the k-space data using the computer system;
(c) generating transform domain data by using the computer system to apply at least one linear transform to the series of images to transform the series of images into a transform domain;
(d) generating denoised data by applying a denoising algorithm in the transform domain data using the computer system;
(e) generating a denoised image by transforming the denoised data to an image domain using the computer system to apply an inverse of the linear transform to the denoised data.

2. The method of claim 1, wherein step (b) includes normalizing the series of images by g-factor maps and step (e) includes re-normalizing the denoised image using the g-factor maps.

3. The method of claim 1, wherein step (c) includes applying the at least one linear transform along at least one spatial dimension of each image in the series of images.

4. The method of claim 1, wherein step (c) includes applying the at least one linear transform across the series of images along a temporal dimension.

5. The method of claim 1, wherein the denoising algorithm comprises a locally low-rank (LLR)-based denoising algorithm.

6. The method of claim 5, wherein the locally low-rank denoising algorithm comprises:
selecting, with the computer system, a patch in the transform domain data corresponding to the series of images;
forming a matrix with the computer system by combining vectors generated using the patch; and
applying a locally low-rank denoising with the computer system using the matrix and the series of images in the transform domain to generate the denoised data.

7. The method of claim 6, wherein the matrix comprises a Casorati matrix.

8. The method of claim 6, wherein the locally low-rank denoising implements a singular value decomposition.

9. The method of claim 8, wherein the locally low-rank denoising implements a singular value thresholding by applying a threshold.

10. The method of claim 9, wherein the threshold is chosen heuristically.

11. The method of claim 9, wherein the threshold is computed based on singular values of a random Gaussian matrix.

12. The method of claim 11, wherein a distribution of entries in the random Gaussian matrix is similar to a distribution of noise in the k-space data accessed in step (a).

13. The method of claim 1, wherein step (d) includes normalizing the series of images in the transform domain by transform space g-factor maps.

14. The method of claim 1, wherein the denoising algorithm is a channel-independent denoising algorithm and the series of images are coil channel images.

15. The method of claim 1, wherein the k-space data accessed with the computer system comprise undersampled k-space data.

16. The method of claim 1, wherein reconstructing images from the k-space data includes a coil combination step and the images of step (b) comprise coil-combined images.

17. The method of claim 1, wherein the series of images comprise at least one of a dynamic series of images or a contrast-varying series of images.

18. The method of claim 1, wherein the linear transform is a unitary transform.

19. The method of claim 18, wherein the unitary transform is at least one of a discrete Fourier transform, a wavelet transform, a discrete cosine transform, or a Walsh Hadamard transform.

20. The method of claim 1, wherein the at least one linear transform is applied to at least one subset of the series of images that includes fewer than all of the images in the series of images.

21. The method of claim 20, wherein the at least one linear transform is applied to a plurality of subsets of the series of images.

22. The method of claim 1, wherein the linear transform is a learned transform.

23. The method of claim 22, wherein the learned transform comprises a machine learning algorithm trained on paired training data, wherein the paired training data comprise a plurality of images paired with corresponding data in the transform domain.

24. A method for denoising magnetic resonance images, the method comprising:
(a) accessing a series of images with a computer system;
(b) applying a linear transform to the series of images using the computer system to generate transform domain data;
(c) generating denoised data by applying a singular value thresholding using a locally low-rank (LLR) model to the transform domain data using the computer system;
(d) generating denoised images from the denoised data by using the computer system to transform the denoised data into image space.

25. The method of claim 24, wherein the series of images correspond to undersampled k-space data, and each image of the series of images contains aliasing artifacts.

26. The method of claim 24, wherein the linear transform is a unitary transform.

27. The method of claim 26, wherein the unitary transform is at least one of a discrete Fourier transform, a wavelet transform, a discrete cosine transform, or a Walsh Hadamard transform.

28. The method of claim 24, wherein the reconstructed images comprise magnitude images.

29. A method for reconstructing denoised magnetic resonance images, the method comprising:
(a) accessing k-space data with a computer system;
(b) generating denoised data by applying a singular value thresholding using a locally low-rank (LLR) model to the k-space data using the computer system; and
(c) generating a denoised image by transforming the denoised data to an image domain using the computer system to apply a first linear transform to the denoised data.

30. The method of claim 29, wherein step (b) comprises applying a second linear transform to the k-space data prior to applying the singular value thresholding using the LLR model; and wherein the second linear transform is an inverse of the first linear transform.
